(19) United States
(12) Patent Application Publication
(10) Pub. No.: US 2024/0258418 A1
(43) Pub. Date: Aug. 1, 2024

(54) TRANSISTOR DEVICES, POWER DEVICES, AND METHOD OF MANUFACTURING THEREOF

(71) Applicant: HUAWEI TECHNOLOGIES CO., LTD., Shenzhen (CN)

(72) Inventor: Gilberto CURATOLA, Nuremberg (DE)

(21) Appl. No.: 18/635,379

(22) Filed: Apr. 15, 2024

Related U.S. Application Data
(63) Continuation of application No. PCT/EP2021/078757, filed on Oct. 18, 2021.

(51) Int. Cl. H01L 29/778; H01L 29/20; H01L 29/66

(52) U.S. Cl. CPC H01L 29/7786; H01L 29/2003; H01L 29/66462

(57) ABSTRACT

A member includes a silicon base substrate layer, a transition layer, a gallium nitride (GaN) buffer, a first aluminum gallium nitride (AlGaN) barrier layer, a first p-doped gallium nitride (pGaN) layer, where a portion of the GaN buffer layer forms a first GaN channel layer. The member further includes a second GaN channel layer, a second AlGaN barrier layer, and a second pGaN layer. The second pGaN layer is connected to the first pGaN layer by a connecting pGaN portion. The member further includes a gate contact, a source contact, and a drain contact, where the first pGaN channel layer is arranged between the source contact and the drain contact.

### CROSS-REFERENCE TO RELATED APPLICATIONS

This application is a continuation of International Application No. PCT/EP2021/078757, filed on Oct. 18, 2021, the disclosure of which is hereby incorporated by reference in its entirety.

### TECHNICAL FIELD

The present disclosure relates generally to the field of semiconductor devices and more specifically, to a member (e.g., a semiconductor structure), transistor devices, power devices, and a method for manufacturing the member with enhanced high voltage operation capability.

### BACKGROUND

Generally, a semiconductor device is based on electronic properties of a semiconductor material, such as silicon (Si), germanium (Ge), and the like, for its functioning. The semiconductor device is generally manufactured either as an individual device or as an integrated circuit (IC) device, for example, using a conventional silicon-based semiconductor technology. However, the conventional silicon-based semiconductor technology has certain limits in terms of on-state resistance versus breakdown voltage. There is a super junction concept that has been extensively proven and applied to the conventional silicon-based semiconductor technology to surpass such limits. In the super junction concept, p-type doped vertical stripes are added in a drift region of the semiconductor device, which results in the formation of new PN-junctions. The super junction concept allows achieving a flat electric field distribution in the semiconductor device due to lateral depletion of an adjacent PN-junction (i.e., cool metal oxide semiconductor (MOS)). Because of the flat electric field distribution, the super junction concept manifests a much higher doping profile and reduces a minimum achievable on-state resistance.

Currently, intensive efforts are taken to develop a possible replacement of the conventional silicon technology (or Si-based field-effect transistors (FETs)), for example, by the development of wide bandgap (WBG) semiconductor materials-based technology. The wide bandgap semiconductor materials provide a partially better performance both at a device level as well as at a system level as compared to the conventional silicon-based semiconductor technology. For example, conventional enhancement-mode gallium nitride (GaN) based power FETs are already used by semiconductor manufacturers in various conventional products. Such wide bandgap semiconductor materials (e.g., gallium nitride) based power FETs (or MOSFET) utilize p-doped GaN normally-off concept that uses, generally, a single aluminium gallium nitride (AlGaN) barrier layer. It is known that GaN based semiconductor devices are by nature normally-on devices, however, power electronics industry, strongly desires normally-off devices. The conventional wide bandgap semiconductor materials-based power transistors manifest several drawbacks. The first drawback is that the threshold voltage and the on-state resistance of the semiconductor device cannot be controlled independently. On the contrary, the on-state resistance of the semiconductor device can be lowered but at the expense of also lowering the threshold voltage (V_{TH}) of the semiconductor device, which is very detrimental because of an increased off-state leakage and because of unwanted risks of the semiconductor device spurious turn-on. Another important drawback of the conventional wide bandgap semiconductor materials-based power transistors is a high electric field at the gate-drain edge of the semiconductor device. The high electric field represents a very serious concern for the reliability of the semiconductor device, which is generally mitigated with the use of a complex field plate design. Thus, the most effective and simplified way to reduce the high (or maximum) electric field and to improve the reliability of the semiconductor device is by sacrificing the overall performance of the semiconductor device, which is again not desirable. Therefore, there exists a technical problem of how to improve the reliability of the semiconductor device without sacrificing the performance of the semiconductor device.

Therefore, in light of the foregoing discussion, there exists a need to overcome the aforementioned drawbacks associated with the conventional semiconductor device.

### SUMMARY

The present disclosure provides a member, transistor devices, power devices, and a method for manufacturing the member. The present disclosure provides a solution to the existing problem of how to improve the reliability of the semiconductor device without sacrificing the performance of the semiconductor device. An objective of the present disclosure is to provide a solution that overcomes at least partially the problems encountered in the prior art and provide an improved member, transistor device, power device, and a method for manufacturing the member with enhanced high voltage operation, where the member effectively improves the performance of a semiconductor device without sacrificing the performance of the semiconductor device.

One or more objectives of the present disclosure is achieved by the solutions provided in the enclosed independent claims. Advantageous implementations of the present disclosure are further defined in the dependent claims.

In one aspect, the present disclosure provides a member comprising, a silicon base substrate layer, a transition layer arranged over the silicon base substrate layer, a gallium nitride (GaN) buffer layer arranged over the transition layer, a first aluminium gallium nitride (AlGaN) barrier layer arranged over the gallium nitride (GaN) buffer layer, and a first p-doped gallium nitride (pGaN) layer arranged over the first aluminium gallium nitride (AlGaN) barrier layer, wherein a portion of the gallium nitride (GaN) buffer layer forming a first gallium nitride (GaN) channel layer, and wherein the first gallium nitride (GaN) channel layer, the first aluminium gallium nitride (AlGaN) barrier layer and the first p-doped gallium nitride (pGaN) layer forming a first epitaxial stack. The member further comprises a second gallium nitride (GaN) channel layer arranged over the first p-doped gallium nitride (pGaN) layer, a second aluminium gallium nitride (AlGaN) barrier layer arranged over the second gallium nitride (GaN) channel layer, a second p-doped gallium nitride (pGaN) layer arranged over the second barrier aluminium gallium nitride (AlGaN) barrier layer, a gate contact arranged over the second p-doped gallium nitride (pGaN) layer, a source contact arranged over the first aluminium gallium nitride (AlGaN) barrier layer, and a drain contact arranged over the first aluminium gallium nitride (AlGaN) barrier layer, wherein the second p-doped gallium nitride (pGaN) layer is connected to the first p-doped gallium nitride (pGaN) layer by a connecting p-doped gallium nitride (pGaN) portion extending through a space in the second aluminium gallium nitride (AlGaN) barrier layer and the second gallium nitride (GaN) channel layer, and wherein the first p-doped gallium nitride (pGaN) layer is arranged between the source contact and the drain contact.

The member of the present disclosure is a semiconductor structure that enables drastic reduction in an electric field peak at an edge of the gate contact and the drain contact (or at gate-drain edge). Moreover, due to the use of the second aluminium gallium nitride barrier layer, a flat electric field distribution is achieved along the first aluminium gallium nitride barrier layer and the second aluminium gallium nitride barrier layer of the member. The member further achieves an improved breakdown voltage (BV), which in turn allows having a drastic reduction in dimensions of a semiconductor device (e.g., a transistor device or a power device) for the same target breakdown voltage. In addition, the first epitaxial stack and the second epitaxial stack of the member are beneficial to improve the performance and overall reliability of the member. Alternatively stated, the disclosed member improves the reliability of a semiconductor device without sacrificing the overall performance of the semiconductor device and manifests an enhanced high voltage operation capability.

In an implementation form, the gate contact is arranged over the connecting p-doped gallium nitride (pGaN) portion.

In this implementation, the gate contact that is arranged over the connecting p-doped gallium nitride portion is also in direct contact with a first p-doped gallium nitride layer and a second p-doped gallium nitride layer. As a result, there is a minimum resistance between the gate contact and the first p-doped gallium nitride layer.

In another implementation form, the connecting p-doped gallium nitride (pGaN) portion connecting the first p-doped gallium nitride (pGaN) layer and second p-doped gallium nitride (pGaN) layer is arranged to extend above an upper surface of the second p-doped gallium nitride (pGaN) layer.

In this implementation, the gate contact arranged over the connecting p-doped gallium nitride portion can be used for further electrical connection with an external power supply.

In yet another implementation form, the first gallium nitride (GaN) channel layer thickness is in the range, the first aluminium gallium nitride (AlGaN) barrier layer thickness is in the range, the first p-doped gallium nitride (pGaN) layer thickness is in the range, the second gallium nitride (GaN) channel layer thickness is in the range, the second aluminium gallium nitride (AlGaN) barrier layer thickness is in the range, and/or the second p-doped gallium nitride (pGaN) layer thickness is in the range.

By virtue of using alternative thickness for different layers, the member can achieve either a desired performance and a desired reliability.

In another implementation form, the first gallium nitride (GaN) channel layer has a doping degree in the range, the first aluminium gallium nitride (AlGaN) barrier layer has a doping degree in the range, the first p-doped gallium nitride (pGaN) layer has a doping degree in the range, the second gallium nitride (GaN) channel layer has a doping degree in the range, the second aluminium gallium nitride (AlGaN) barrier layer has a doping degree in the range, and/or the second p-doped gallium nitride (pGaN) layer has a doping degree in the range.

The doping degree can be adjusted for different layers of the member so that the member can achieve a desired performance as well as a desired reliability.

In yet another implementation form, the member further comprises a passivation layer arranged over the second p-doped gallium nitride (pGaN) layer and wherein the connecting p-doped gallium nitride (pGaN) portion extends through in the passivation layer.

The passivation layer is beneficial to prevent oxidation of the second p-doped gallium nitride layer.

In another implementation form, the passivation layer extends between the source contact and the first p-doped gallium nitride (pGaN) layer and between the drain contact and the first p-doped gallium nitride (pGaN) layer.

In this implementation, the passivation layer provides a lateral isolation between the source contact, and the first p-doped gallium nitride layer, and also between the drain contact and the first p-doped gallium nitride layer. Moreover, the passivation layer reduces all possible leakage paths, especially at high voltage.

In yet another implementation form, the passivation layer comprises aluminium oxide, aluminium nitride, silicon dioxide or silicon nitride.

The passivation layer provides an improved isolation between the source contact and the first p-doped gallium nitride layer, and between the drain contact and the first p-doped gallium nitride layer.

In another implementation form, the member further comprises at least one intermediate gallium nitride (GaN) channel layer, at least one intermediate aluminium gallium nitride (AlGaN) barrier layer arranged over the at least one intermediate gallium nitride (GaN) channel layer and at least one intermediate p-doped gallium nitride (pGaN) layer arranged over the at least one intermediate aluminium gallium nitride (AlGaN) barrier layer respectively, wherein the at least one intermediate gallium nitride (GaN) barrier layer, the at least one intermediate aluminium gallium nitride (AlGaN) barrier layer and the at least one intermediate p-doped gallium nitride (pGaN) layer are arranged between the first gallium nitride (GaN) channel layer, the first aluminium gallium nitride (AlGaN) barrier layer, the first p-doped gallium nitride (pGaN) layer and the second gallium nitride (GaN) channel layer, the second aluminium gallium nitride (AlGaN) barrier layer, the second p-doped gallium nitride (pGaN) layer.

By virtue of using the at least one intermediate gallium nitride channel layer, the at least one intermediate aluminium gallium nitride barrier layer, and the at least one intermediate p-doped gallium nitride layer, the member achieves an improved reliability.

In yet another implementation form, the first gallium nitride (GaN) channel layer comprises an un-intentionally doped (UID) layer.

Beneficially, the aluminium gallium nitride layer of the gallium nitride buffer layer provides an improved electrical connection with the first aluminium gallium nitride barrier layer.

In another implementation form, at least one of the drain contact, the gate contact and/or the source contact is ohmic, Schottky and/or metal.

By virtue of using the ohmic, Schottky and/or metal, an improved electrical connection is obtained through the gate contact, the source contact, and the drain contact of the member.

In another aspect, the present disclosure provides a metal-semiconductor field-effect transistor (MESFET) device comprising a member.

The metal-semiconductor field-effect transistor (MESFET) device achieves all the advantages and technical effects of the member of the present disclosure.

In yet another aspect, the present disclosure provides a power device comprising the member.

The power device achieves all the advantages and technical effects of the member of the present disclosure.

In another aspect, the present disclosure provides a method for manufacturing a member, wherein the method comprises arranging a gallium nitride (GaN) buffer layer arranged over a transition layer arranged over a silicon base substrate layer, arranging a first aluminium gallium nitride (AlGaN) barrier layer over the gallium nitride (GaN) buffer layer, arranging a first p-doped gallium nitride (pGaN) layer over the first aluminium gallium nitride (AlGaN) barrier layer, arranging a second gallium nitride (GaN) channel layer over the first pGaN layer, arranging a second aluminium gallium nitride (AlGaN) barrier layer over the second gallium nitride (GaN) channel layer, arranging a second p-doped gallium nitride (pGaN) layer over the second barrier aluminium gallium nitride (AlGaN) layer, arranging a gate contact over the second p-doped gallium nitride (pGaN) layer, arranging a source contact over the first aluminium gallium nitride (AlGaN) layer, arranging a drain contact over the first aluminium gallium nitride (AlGaN) layer, arranging a sacrificial passivation layer over the p-doped gallium nitride (pGaN) layer, forming a space in the sacrificial passivation layer, the second p-doped gallium nitride (pGaN) layer, the second aluminium gallium nitride (AlGaN) barrier layer and the second gallium nitride (GaN) channel layer, and connecting the first p-doped gallium nitride (pGaN) layer with the second p-doped gallium nitride (pGaN) layer by arranging a connecting p-doped gallium nitride (pGaN) portion extending in the space.

The method achieves all the advantages and technical effects of the member of the present disclosure.

It is to be appreciated that all the aforementioned implementation forms can be combined. It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIGS. 1A and 1B are schematic illustrations of a member, in accordance with different embodiments of the present disclosure;

FIG. 2A is a schematic illustration of a member, in accordance with another embodiment of the present disclosure;

FIG. 2B is a schematic illustration of a member, in accordance with yet another embodiment of the present disclosure;

FIG. 2C is a schematic illustration of a member, in accordance with another embodiment of the present disclosure;

FIG. 2D is a schematic illustration of a member, in accordance with yet another embodiment of the present disclosure;

FIG. 2E is a schematic illustration of a member, in accordance with another embodiment of the present disclosure;

FIG. 2F is a schematic illustration of a member, in accordance with yet another embodiment of the present disclosure;

FIG. 2G is a schematic illustration of a member, in accordance with another embodiment of the present disclosure;

FIG. 3 is a schematic illustration of a member, in accordance with another embodiment of the present disclosure;

FIG. 4 is a schematic illustration of a member, in accordance with yet another embodiment of the present disclosure;

FIG. 5 is a schematic illustration of a member, in accordance with another embodiment of the present disclosure;

FIG. 6 is a flowchart of an exemplary method for an exemplary manufacturing a member, in accordance with an embodiment of the present disclosure;

FIG. 7A is a graphical representation that illustrates an electric field cut along a direction of a gallium nitride channel layer within an aluminium gallium nitride barrier layer, during off-state conditions, in accordance with an embodiment of the present disclosure;

FIG. 7B is a graphical representation that illustrates an electric field cut along a direction of a gallium nitride channel layer within an aluminium gallium nitride barrier layer, during off-state conditions, for different p-type doping degree in the p-doped gallium nitride layer, in accordance with an embodiment of the present disclosure;

FIG. 8 is a block diagram of a metal-semiconductor field-effect transistor (MESFET) device, in accordance with an embodiment of the present disclosure; and

FIG. 9 is a block diagram of a power device, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

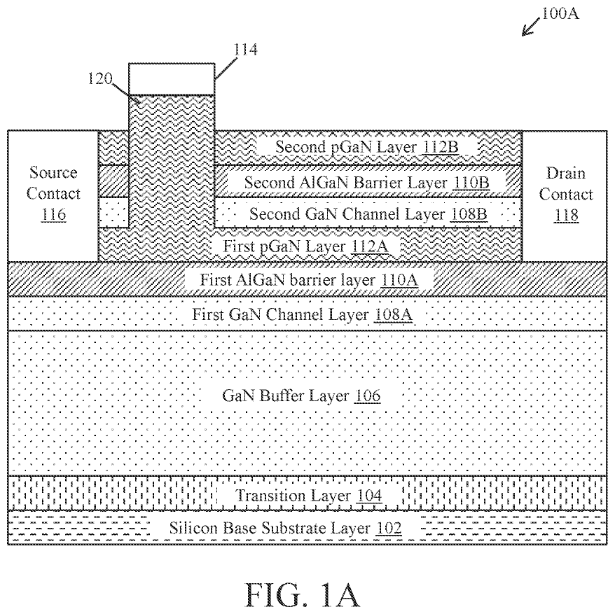

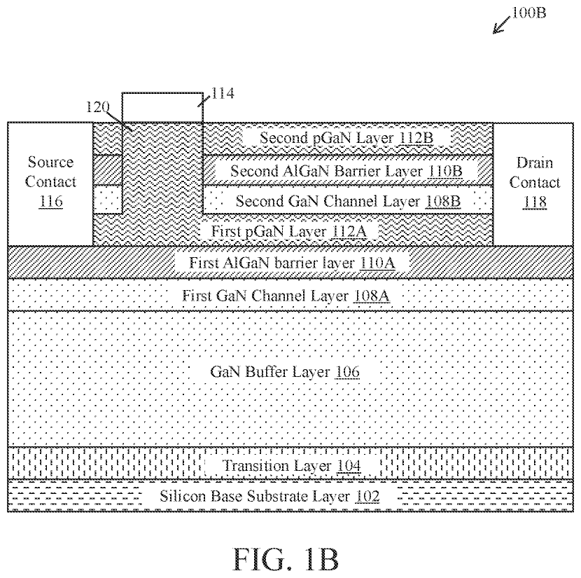

FIGS. 1A and 1B are schematic illustrations of a member, in accordance with different embodiments of the present disclosure. With reference to FIGS. 1A and 1B, there is shown a schematic illustration of a member, such as a member 100A (of FIG. 1A) and a member 100B (of FIG. 1B), each of which includes a silicon base substrate layer 102, a transition layer 104, a gallium nitride (GaN) buffer layer 106, a first gallium nitride (GaN) channel layer 108A, and a second gallium nitride (GaN) channel layer 108B. There is further shown a first aluminium gallium nitride (AlGaN) barrier layer 110A, a second aluminium gallium nitride (AlGaN) barrier layer 110B, a first p-doped gallium nitride (pGaN) layer 112A, and a second p-doped gallium nitride (pGaN) layer 112B. There is further shown a gate contact 114, a source contact 116, a drain contact 118, and a connecting p-doped gallium nitride (pGaN) portion 120.

The member 100A is a semiconductor structure that includes one or more layers of semiconductor material. In an example, the semiconductor material of one layer may be the same (or different) as compared to the semiconductor material of another layer. The member 100A may also comprise layers or structures of materials other than the semiconductor materials. Further, the member 100A may constitute a semiconductor device or be comprised in the semiconductor device. The semiconductor structure of the member 100A of FIG. 1A is same as that of FIG. 1B, however in the member 100B, there is a slight difference in terms of arrangement of the second p-doped gallium nitride layers 112B, which does not protrude above an upper surface of the second p-doped gallium nitride layer 112B.

The silicon base substrate layer 102 is a thin slice of semiconductor material, which may also be referred to as a single wafer or a chip. The silicon base substrate layer 102 acts as a base of the member 100A. Due to its abundant availability, the silicon base substrate layer 102 is a low-cost material. The silicon base substrate layer 102 is available in different sizes, such as a size of six-inch (6″), eight-inch (8″), and twelve-inch (12″).

The transition layer 104 is a layer of a material (e.g., compositionally graded material), which is used to provide sufficient strain relief, and to limit or prevent the formation of cracks in the gallium nitride buffer layer 106.

The gallium nitride buffer layer 106 is a layer of gallium nitride semiconductor material, which is a wide-bandgap (WBG) semiconductor material. The bandgap of the gallium nitride buffer layer 106 is of a value of 3.4 electron volt (eV). In an example, the gallium nitride buffer layer 106 is doped with dopant elements (e.g., carbon or iron). Moreover, such dopant elements act as a p-type doping and effectively increase the breakdown strength of the first epitaxial stack (or epitaxial layer) as well as it contributes to a significant decrease in the lateral parasitic leakage current.

The first gallium nitride channel layer 108A, and the second gallium nitride channel layer 108B are the layers of gallium nitride semiconductor material.

The first aluminium gallium nitride barrier layer 110A, and the second aluminium gallium nitride barrier layer 110B are the layers of a semiconductor material. In an example, the first aluminium gallium nitride barrier layer 110A, and the second aluminium gallium nitride barrier layer 110B acts as a barrier layer.

The first p-doped gallium nitride layer 112A and the second p-doped gallium nitride (pGaN) layer 112B are the layers of gallium nitride semiconductor material p-type dopants (e.g., magnesium (Mg)). Similarly, the connecting p-doped gallium nitride (pGaN) portion 120 is a layer of gallium nitride semiconductor material p-type dopants, and which acts as a connecting layer.

The gate contact 114, the source contact 116, and the drain contact 118 correspond to a metal gate contact, a metal source contact, and a metal drain contact terminal of a semiconductor device. The gate contact 114, the source contact 116, and the drain contact 118 are used for connection purposes (e.g., to connect the semiconductor device to a power supply).

In one aspect, the present disclosure provides the member 100A that comprises, the silicon base substrate layer 102, the transition layer 104 arranged over the silicon base substrate layer 102, the gallium nitride (GaN) buffer layer 106 arranged over the transition layer 104. In other words, the silicon base substrate layer 102 of the member 100A acts as a base of the member 100A. Further, the transition layer 104 is arranged over the silicon base substrate layer 102, where the transition layer 104 is in direct contact with the silicon base substrate layer 102. In an example, there are two possible approaches for the composition of the transition layer 104, such as a graded buffer approach, and a superlattice approach. In the graded buffer approach, the transition layer 104 is composed of an aluminium nitride (AIN) layer (or a nucleation layer). For example, the aluminium nitride layer is directly arranged on top of the silicon base substrate layer 102, followed by a sequence of aluminium gallium nitride (AlGaN) layers (e.g., three or more layers), where the content of aluminium in the aluminium nitride layer is decreasing gradually from 100% to 0. Instead, in the superlattice approach, the aluminium nitride layer (or a nucleation layer) is directly arranged on top of the silicon base substrate layer 102, followed by a superlattice, where the superlattice is composed of a stack of aluminium nitride/aluminium gallium nitride (AIN/AlGaN) layers, and the superlattice is repeated several times (e.g., from 30 times to 100 times). Thereafter, the member 100A further includes the gallium nitride buffer layer 106 arranged on the transition layer 104. In other words, the gallium nitride buffer layer 106 is arranged on the silicon base substrate layer 102, such as to form a GaN-On-Si substrate, as shown in FIG. 1A. Beneficially, the transition layer 104 provides sufficient strain relief and also limits (or prevents) the formation of cracks in the gallium nitride buffer layer 106.

The member 100A further comprises the first aluminium gallium nitride (AlGaN) barrier layer 110A arranged over the gallium nitride (GaN) buffer layer 106. The first p-doped gallium nitride (pGaN) layer 112A is arranged over the first aluminium gallium nitride (AlGaN) barrier layer 110A, where a portion of the gallium nitride (GaN) buffer layer 106 forms a first gallium nitride (GaN) channel layer 108A. The first gallium nitride (GaN) channel layer 108A, the first aluminium gallium nitride (AlGaN) barrier layer 110A and the first p-doped gallium nitride (pGaN) layer 112A forms the first epitaxial stack. In other words, the member 100A includes the first epitaxial stack, which is formed from three different layers, such as the first gallium nitride channel layer 108A, the first aluminium gallium nitride barrier layer 110A and the first p-doped gallium nitride layer 112A. As, the first gallium nitride channel layer 108A is formed from the portion of the gallium nitride buffer layer 106, thus the first gallium nitride channel layer 108A is in direct contact with the gallium nitride buffer layer 106. Moreover, the member 100A makes use of the properties of the gallium nitride buffer layer 106 to achieve improved electrical performance, for example, breakdown voltage (BV) for different semiconductor devices. The member 100A provides a new device concept that makes use of a stacked-layer approach, and as well as the use of p-type doped gallium nitride, such as the first p-doped gallium nitride layer 112A. In an example, the member 100A provides a contemporary use of a two-dimensional electron gas (2DEG) that forms at an interface between the first aluminium gallium nitride barrier layer 110A, and the first gallium nitride channel layer 108A. In an example, the two-dimensional electron gas is a scientific model in solid-state physics, where the two-dimensional electron gas is free to move in two dimensions, but tightly confined in a third dimension. Moreover, such tight confinement leads to quantized energy levels for a motion of the two-dimensional electron gas in the third dimension, which can then be ignored for most problems. Thus, the two-dimensional electron gas appears to be a two-dimensional (2D) sheet embedded in a three-dimensional (3D) world. Beneficially, by virtue of using the two-dimensional electron gas, the member 100A is less prone to dynamic effects due to surface defects, and also to thickness variation caused by process variations (e.g., etching of p-doped gallium nitride). The two-dimensional electron gas has high mobility. Moreover, due to the quantum confinement and reduced intervalley scattering the carrier mobility increases. Moreover, due to the presence of the two-dimensional electron gas, a channel is not formed at an oxide/semiconductor interface of the member 100A, as formed in conventional metal oxide silicon field effect transistor (or MOSFET), but rather formed at a semiconductor/semiconductor interface. This, also increases the mobility of the two-dimensional electron gas. In addition, the reduced sensitivity to surface effects and better dynamic behavior is one of the advantages of the member 100A as compared with state of the art.

The member 100A further comprises the second gallium nitride (GaN) channel layer 108B arranged over the first p-doped gallium nitride (pGaN) layer 112A, the second aluminium gallium nitride (AlGaN) barrier layer 110B arranged over the second gallium nitride (GaN) channel layer 108B, and the second p-doped gallium nitride (pGaN) layer 112B arranged over the second aluminium gallium nitride (AlGaN) barrier layer 110B. The member 100A further includes three other layers, which are formed on the first epitaxial stack. In other words, a second epitaxial stack is formed above the first second epitaxial stack, such as the second epitaxial stack includes the second gallium nitride channel layer 108B, the second aluminium gallium nitride barrier layer 110B, and the second p-doped gallium nitride layer 112B. The second gallium nitride channel layer 108B is arranged over the first p-doped gallium nitride layer 112A, the second aluminium gallium nitride barrier layer 110B is arranged over the second gallium nitride channel layer 108B, and the second p-doped gallium nitride layer 112B is arranged over the second aluminium gallium nitride barrier layer 110B. Like the first epitaxial stack, the member 100A provides the contemporary use of the two-dimensional electron gas that forms at an interface between the second aluminium gallium nitride barrier layer 110B, and the second gallium nitride channel layer 108B. As a result, the member 100A achieves enhanced capability for high voltage operation.

The member 100A further comprises the gate contact 114 arranged over the second p-doped gallium nitride (pGaN) layer 112B, the source contact 116 arranged over the first aluminium gallium nitride (AlGaN) barrier layer 110A, and the drain contact 118 arranged over the first aluminium gallium nitride (AlGaN) barrier layer 110A. The second p-doped gallium nitride (pGaN) layer 112B is connected to the first p-doped gallium nitride (pGaN) layer 112A by the connecting p-doped gallium nitride (pGaN) portion 120 extending through a space in the second aluminium gallium nitride (AlGaN) barrier layer 110B and the second gallium nitride (GaN) channel layer 108B. Moreover, the first p-doped gallium nitride (pGaN) layer 112A is arranged between the source contact 116 and the drain contact 118. In other words, the member 100A further includes the space formed (e.g., via etching) in the second p-doped gallium nitride (pGaN) layer 112B, the second aluminium gallium nitride barrier layer 110B, the second gallium nitride channel layer 108B, and the first p-doped gallium nitride (pGaN) layer 112A. The member 100A further includes the connecting p-doped gallium nitride portion 120, which extends through the space, so as to connect the second p-doped gallium nitride layer 112B to the first p-doped gallium nitride layer 112A. In an example, a recess is arranged (e.g., via etching) at each end of the member 100A, such as at a left end as well as at a right end of the member 100A. As a result, the first aluminium gallium nitride barrier layer 110A is exposed from a top view of the member 100A (e.g., exposed or visible at both ends of the member 100A), and through the recess that is formed at both ends of the member 100A. Thereafter, the source contact 116, and the drain contact 118 are arranged at two opposite ends of the first aluminium gallium nitride barrier layer 110A. For example, the source contact 116 is arranged at the left end of the first aluminium gallium nitride barrier layer 110A, and the drain contact 118 is arranged at the right end of the first aluminium gallium nitride barrier layer 110A, as shown in FIG. 1A. As a result, the first p-doped gallium nitride layer 112A is arranged between the source contact 116 and the drain contact 118. In addition, the gate contact 114 is arranged over the second p-doped gallium nitride layer 112B. In an example, the gate contact is arranged over the connecting p-doped gallium nitride portion 120, which is beneficial to deplete a two-dimensional electron gas below the gate contact 114 and also to allow a normally off device operation of the member 100A.

In an implementation, the recess is formed at both ends of the member 100A in order to etch away completely the first aluminium gallium nitride barrier layer 110A. Since the first aluminium gallium nitride barrier layer 110A has been removed completely, thus, the gallium nitride buffer layer 106 will be exposed though the recess. Thereafter, the source contact 116 is arranged at the left end of the gallium nitride buffer layer 106, and the drain contact 118 is arranged at the right end of the gallium nitride buffer layer 106. Thus, the resulted member would look exactly the same as that of the member 100A of the FIG. 1A or the member 100B of the FIG. 1B with the exception that the source contact 116, and the drain contact 118 are now in direct contact with the gallium nitride buffer layer 106.

The member 100A enables a drastic (or massive) reduction in an electric field peak at an edge of the gate contact 114 and the drain contact 118 (or at gate-drain edge). Moreover, by use of the second aluminium gallium nitride barrier layer 110B, a flat electric field distribution is achieved along the first aluminium gallium nitride barrier layer 110A and the second aluminium gallium nitride barrier layer 110B. In addition, the member 100A achieves an improved breakdown voltage (BV), which allows to have a drastic reduction in dimensions of a semiconductor device (e.g., a transistor device, a power device) for the same target breakdown voltage. In addition, the member 100A is beneficial to improve the reliability (or high-temperature reverse bias (HTRB) reliability) of the semiconductor device without sacrificing the overall performance of the semiconductor device.

In accordance with an embodiment, the gate contact 114 is arranged over the connecting p-doped gallium nitride (pGaN) portion 120. As the connecting p-doped gallium nitride portion 120 connects the first p-doped gallium nitride layer 112A and the second p-doped gallium nitride layer 112B. Therefore, the gate contact 114 arranged over the connecting p-doped gallium nitride portion 120 is also in direct contact with the first p-doped gallium nitride layer 112A and the second p-doped gallium nitride layer 112B. Beneficially, there is a minimum resistance between the gate contact 114 and the first p-doped gallium nitride layer 112A.

In accordance with an embodiment, the connecting p-doped gallium nitride (pGaN) portion 120 connecting the first p-doped gallium nitride (pGaN) layer 112A and the second p-doped gallium nitride (pGaN) layer 112B is arranged to extend above an upper surface of the second p-doped gallium nitride (pGaN) layer 112B. In other words, the connecting p-doped gallium nitride portion 120 is configured to connect the first p-doped gallium nitride layer 112A and the second p-doped gallium nitride layer 112B. In an example, the connecting p-doped gallium nitride portion 120 extend (or as in protrude) above the upper surface of the second p-doped gallium nitride layer 112B. As a result, the gate contact 114 arranged over the connecting p-doped gallium nitride (pGaN) portion 120, will be an extended gate contact.

In an implementation, the connecting p-doped gallium nitride portion 120 is arranged above the upper surface of the second p-doped gallium nitride (pGaN) layer 112B, but does not extend above the upper surface of the second p-doped gallium nitride layer 112B (as further shown in FIG. 1B). As a result, the gate contact 114 arranged over the connecting p-doped gallium nitride portion 120 can be used for further electrical connection with an external supply.

In accordance with an embodiment, the first gallium nitride (GaN) channel layer 108A has a first gallium nitride (GaN) channel layer thickness, and the first aluminium gallium nitride (AlGaN) barrier layer 110A has a first aluminium gallium nitride (AlGaN) barrier layer thickness. Similarly, the first p-doped gallium nitride (pGaN) layer 112A also has a first p-doped gallium nitride (pGaN) layer thickness. Similarly, the second gallium nitride (GaN) channel layer 108B has a second gallium nitride (GaN) channel layer thickness, and the second aluminium gallium nitride (AlGaN) barrier layer 110B has a second aluminium gallium nitride (AlGaN) barrier layer thickness. The second p-doped gallium nitride (pGaN) layer 112B also has a second p-doped gallium nitride (pGaN) layer thickness . The second gallium nitride (GaN) channel layer thickness equals the first gallium nitride (GaN) channel layer thickness. The second aluminium gallium nitride (AlGaN) barrier layer thickness equals the first aluminium gallium nitride (AlGaN) barrier layer thickness and/or the second p-doped gallium nitride (pGaN) layer thickness equals the first p-doped gallium nitride (pGaN) layer thickness. In other words, the thickness of a layer of the first epitaxial stack is equal to the thickness of a corresponding layer of the second epitaxial stack. For example, the thickness of the first gallium nitride channel layer 108A is equal to the thickness of the second gallium nitride channel layer 108B, and the thickness of the first aluminium gallium nitride barrier layer 110A is equal to the thickness of the second aluminium gallium nitride barrier layer 110B, and the like. Alternatively stated, different layers of the first epitaxial stack are of same thickness as that of the corresponding layers of the second epitaxial stack. By virtue of using the same thickness for the different layers of the first epitaxial stack as well as for the different layers of the second epitaxial stack, the overall performance, as well as reliability of the member 100A, is improved. Moreover, an overall cost of production of the member 100A is reduced.

In accordance with an embodiment, the first gallium nitride (GaN) channel layer 108A has a first gallium nitride (GaN) channel layer thickness, and the first aluminium gallium nitride (AlGaN) barrier layer 110A has a first aluminium gallium nitride (AlGaN) barrier layer thickness. Similarly, the first p-doped gallium nitride (pGaN) layer 112A also has a first p-doped gallium nitride (pGaN) layer thickness. The second gallium nitride (GaN) channel layer 108B has a second gallium nitride (GaN) channel layer thickness, and the second aluminium gallium nitride (AlGaN) barrier layer 110B has a second aluminium gallium nitride (AlGaN) barrier layer thickness. Similarly, the second p-doped gallium nitride (pGaN) layer 112B also has a second p-doped gallium nitride (pGaN) layer thickness. The second gallium nitride (GaN) channel layer thickness differs from the first gallium nitride (GaN) channel layer thickness. The second aluminium gallium nitride (AlGaN) barrier layer thickness differs from the first aluminium gallium nitride (AlGaN) barrier layer thickness, and the second p-doped gallium nitride (pGaN) layer thickness differs from the first p-doped gallium nitride (pGaN) layer thickness. In other words, the thickness of a layer of the first epitaxial stack is different from the thickness of a corresponding layer of the second epitaxial stack. Alternatively stated, different layers of the first epitaxial stack are of different thicknesses as compared to the thickness of the corresponding layers in the second epitaxial stack. Therefore, the thickness of the different layers of the first epitaxial stack as well as for the second epitaxial stack can be manipulated, so that the member 100A can achieve a desired performance as well as a desired reliability.

In accordance with an embodiment, the first gallium nitride (GaN) channel layer thickness is in the range, the first aluminium gallium nitride (AlGaN) barrier layer thickness is in the range, and the first p-doped gallium nitride (pGaN) layer thickness is in the range. The second gallium nitride (GaN) channel layer thickness is in the range, the second aluminium gallium nitride (AlGaN) barrier layer thickness is in the range, and/or the second p-doped gallium nitride (pGaN) layer thickness is in the range. In other words, the thickness of a layer of the first epitaxial stack is alternative to the thickness of a corresponding layer of the second epitaxial stack. For example, the first gallium nitride channel layer thickness ranges between 100 nanometre (nm) to 500 nm, while the second gallium nitride channel layer thickness ranges between 10 nm to 200 nm. Similarly, the first aluminium gallium nitride barrier layer thickness ranges between 10 nm to 30 nm, while the second aluminium gallium nitride barrier layer thickness ranges between 10 nm to 30 nm. Moreover, the first p-doped gallium nitride layer thickness, as well as the second p-doped gallium nitride layer thickness, ranges between 5 nm to 100 nm. In an example, the connecting p-doped gallium nitride portion 120 also has a thickness that ranges between 60 nm and 500 nm.

In an implementation, a thinner layer is beneficial to improve the performance of the member 100A, and a thicker layer is beneficial to improve the reliability of the member 100A. Therefore, by virtue of using alternative thickness for different layers, the member 100A can achieve either the desired performance and the desired reliability.

In accordance with an embodiment, the first gallium nitride (GaN) channel layer 108A has a doping degree in the range, the first aluminium gallium nitride (AlGaN) barrier layer has a doping degree in the range, and the first p-doped gallium nitride (pGaN) layer has a doping degree in the range. The second gallium nitride (GaN) channel layer has a doping degree in the range, the second aluminium gallium nitride (AlGaN) barrier layer has a doping degree in the range, and/or the second p-doped gallium nitride (pGaN) layer has a doping degree in the range. In other words, each layer of the first epitaxial stack as well as of the second epitaxial stack has the range of the doping degree. For example, the doping degree for the first aluminium gallium nitride barrier layer 110A as well as for the second aluminium gallium nitride barrier layer 110B has an aluminium content between 15% and 25%. Similarly, the doping degree for the first p-doped gallium nitride layer 112A as well as for the second p-doped gallium nitride layer 112B has a p-type concentration between 1e¹⁷ cubic centimetres (cm⁻³) and 5e¹⁸ cm⁻³. In an example, the first p-doped gallium nitride layer 112A as well as for the second p-doped gallium nitride layer 112B is doped via magnesium (Mg). In an example, the connecting p-doped gallium nitride portion 120 also has a doping degree that ranges between 1e¹⁸ cm⁻³ and 5e¹⁹ cm⁻³. In an implementation, a high doping degree is beneficial to improve the performance of the member 100A, and a lower doping degree is beneficial to improve the reliability of the member 100A. Therefore, the doping degree can be adjusted for different layers of the member 100A, so that the member 100A can achieve the desired performance as well as the desired reliability.

In an implementation, as the doping degree (and thickness) is increased (e.g., up to a certain point) for the first p-doped gallium nitride layer 112A as well as for the second p-doped gallium nitride layer 112B, the electric field in the member 100 is reduced. As a result, the overall reliability of the member 100A is improved. Therefore, the doping degree (and thickness) can be manipulated for the first p-doped gallium nitride layer 112A as well as for the second p-doped gallium nitride layer 112B, so that the member 100A can achieve either the desired performance (figure of merits) or the desired reliability.

In accordance with an embodiment, the first gallium nitride (GaN) channel layer 108A comprises an un-intentionally doped (UID) layer. In an implementation, the gallium nitride un-intentionally doped layer (UID) is a portion or the totality of the first gallium nitride (GaN) channel layer 108A that is not intentionally doped with dopants elements (n-type nor p-type). Moreover, the gallium nitride buffer layer 106 is doped with carbon or iron (i.e., with p-type dopant) to increase the breakdown strength of the gallium nitride buffer layer 106.

In accordance with an embodiment, at least one of the drain contact 118, the gate contact 114 and/or the source contact 116 is ohmic, and/or Schottky. As the gate contact 114, the source contact 116, and the drain contact 118 are used for current flow and for further electrical connection purposes. Therefore, by virtue of using the ohmic, Schottky and/or metal, an improved electrical connection is obtained through the gate contact 114, the source contact 116, and the drain contact 118 of the member 100A.

The member 100A enables drastic reduction in an electric field peak at an edge of the gate contact 114 and the drain contact 118 (or at the gate-drain edge). Moreover, due to the use of the second aluminium gallium nitride barrier layer 110B, a flat electric field distribution is achieved along the first aluminium gallium nitride barrier layer 110A, and the second aluminium gallium nitride barrier layer 110B of the member 100A. The member 100A further achieves an improved breakdown voltage (BV), which in turn allows to have a drastic reduction in dimensions of the semiconductor device for the same target breakdown voltage. In addition, the first epitaxial stack and the second epitaxial stack of the member 100A are beneficial to improve the performance as well as reliability of the member 100A. The member 100A is also beneficial to improve the reliability of a semiconductor device without sacrificing the overall performance of the semiconductor device and manifests an enhanced high voltage operation capability.

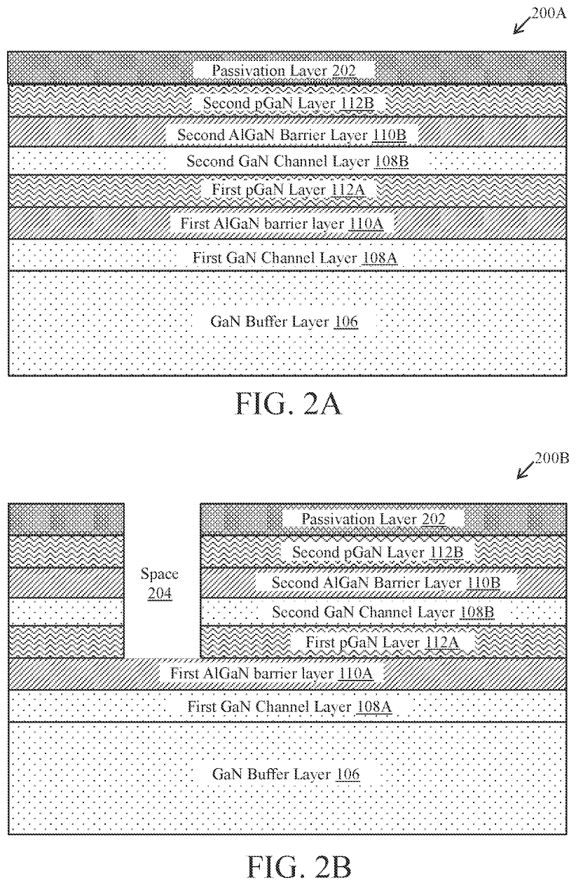

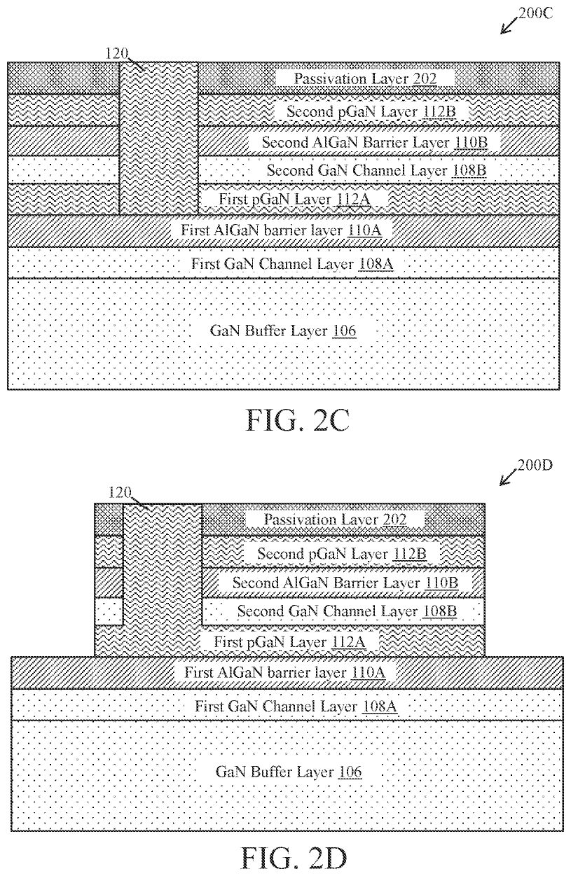

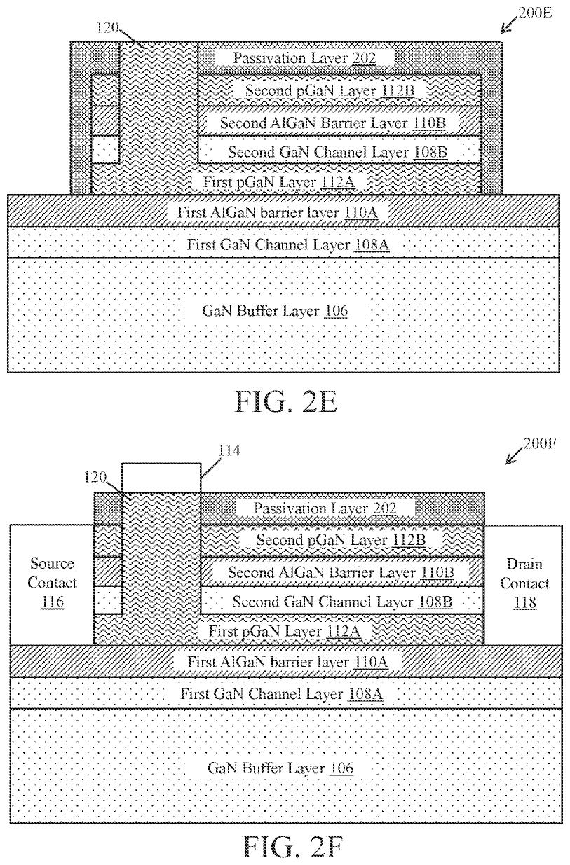

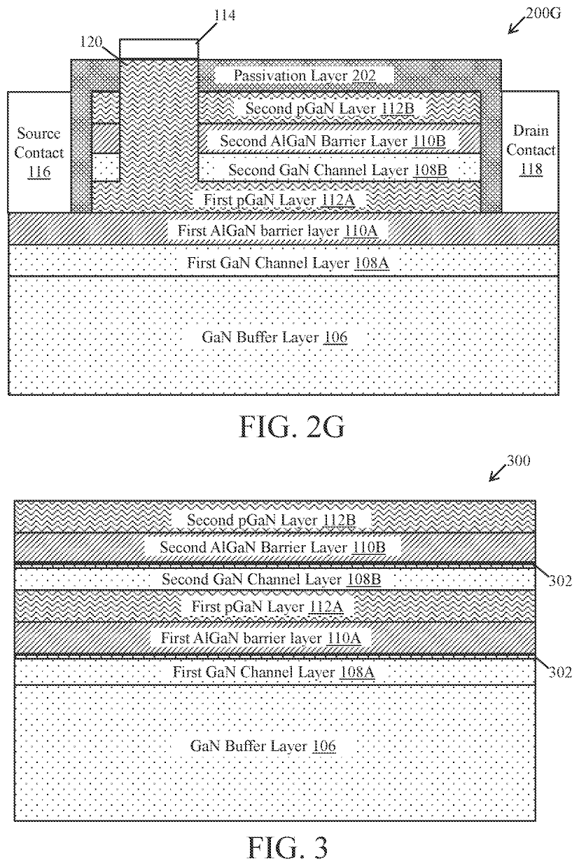

FIG. 2A is a schematic illustration of a member, in accordance with another embodiment of the present disclosure. FIG. 2A is described in conjunction with elements from the FIGS. 1A and 1B. With reference to FIG. 2A, there is shown a schematic illustration of a member 200A that includes a passivation layer 202, the gallium nitride buffer layer 106, the first gallium nitride channel layer 108A, and the second gallium nitride channel layer 108B. The member 200A further includes the first aluminium gallium nitride barrier layer 110A, the second aluminium gallium nitride barrier layer 110B, the first p-doped gallium nitride layer 112A, and the second p-doped gallium nitride layer 112B.

The passivation layer 202 is configured to prevent oxidation of the second p-doped gallium nitride layer 112B. Examples of the passivation layer 202 include, but are not limited to, the aluminium oxide, aluminium nitride, silicon dioxide, the silicon nitride, and the like. The passivation layer 202 is intended to avoid regrowth of the connecting p-doped gallium nitride portion 120 on top of the second p-doped gallium nitride layer 112B (or subsequent p-doped gallium nitride layer, and the like). Moreover, in the absence of the passivation layer 202, the regrowth of the connecting p-doped gallium nitride portion 120 may be everywhere and not limited only to the region inside the trench.

In accordance with an embodiment, the member 200A further comprises a passivation layer 202 arranged over the second p-doped gallium nitride (pGaN) layer 112B and the connecting p-doped gallium nitride (pGaN) portion 120 extends through in the passivation layer 202. In other words, the member 200A includes the passivation layer 202 that is arranged over the second p-doped gallium nitride layer 11B, which further results in the formation of a passivated p-doped gallium nitride. The passivation layer 202 is beneficial to prevent oxidation of the second p-doped gallium nitride layer 112B.

FIG. 2B is a schematic illustration of a member, in accordance with yet another embodiment of the present disclosure. FIG. 2B is described in conjunction with elements from the FIGS. 1A, 1B and 2A. With reference to FIG. 2B, there is shown a schematic illustration of a member 200B that includes a space 204, the gallium nitride buffer layer 106, the first gallium nitride channel layer 108A, and the second gallium nitride channel layer 108B. The member 200B further includes the first aluminium gallium nitride barrier layer 110A, the second aluminium gallium nitride barrier layer 110B, the first p-doped gallium nitride layer 112A, the second p-doped gallium nitride layer 112B, and the passivation layer 202.

The space 204 may also be referred to as a trench, an opening, or a hole. In an example, the space 204 is formed via lithography etching, photolithography, or e-beam lithography.

In an implementation, the passivation layer 202 is initially deposited over the second p-doped gallium nitride layer 112B. Thereafter, the passivation layer 110 is removed from one point along with the passivation layer 110, the second p-doped gallium nitride layer 112B, the second aluminium gallium nitride barrier layer 110B, the second gallium nitride channel layer 108B, and the first p-doped gallium nitride layer 112A. As a result, the space 204 is defined within the member 200B. Moreover, the first p-doped gallium nitride layer 112A is exposed through the space 204, as shown in FIG. 2B. The space 204 is beneficial for a selective arrangement of the connecting p-doped gallium nitride portion 120.

FIG. 2C is a schematic illustration of a member, in accordance with another embodiment of the present disclosure. FIG. 2C is described in conjunction with elements from the FIGS. 1A, 1B, 2A and 2B. With reference to FIG. 2C, there is shown a schematic illustration of a member 200C that includes the gallium nitride buffer layer 106, the first gallium nitride channel layer 108A, and the second gallium nitride channel layer 108B. The member 200C further includes the first aluminium gallium nitride barrier layer 110A, the second aluminium gallium nitride barrier layer 110B, the first p-doped gallium nitride layer 112A, the second p-doped gallium nitride layer 112B, and the passivation layer 202.

In accordance with an embodiment, the connecting p-doped gallium nitride (pGaN) portion 120 extends through in the passivation layer 202. In an example, the passivation layer 202 is removed vertically from one point along with other layers of the member 200C. As a result, the space 204 is defined on the passivation layer 202, the second p-doped gallium nitride layer 112B, the second aluminium gallium nitride barrier layer 110B, and the second gallium nitride channel layer 108B. Thereafter, the connecting p-doped gallium nitride portion 120 is arranged in the space 204 and also over the first p-doped gallium nitride layer 112A, as shown in FIG. 2C. Therefore, selective placement of the connecting p-doped gallium nitride portion 120 is performed on the first aluminium gallium nitride buffer layer 110A that extends up to the surface. Moreover, the connecting p-doped gallium nitride portion 120 is in direct contact with the first p-doped gallium nitride layer 112A, and also in contact with the second p-doped gallium nitride layer 112B. In addition, the passivation layer 202 arranged near the connecting p-doped gallium nitride portion 120 is beneficial to prevent oxidation of the connecting p-doped gallium nitride portion 120. The passivation layer 202 further avoids regrowth of the connecting p-doped gallium nitride portion 120 on top of the second p-doped gallium nitride layer 112B (or subsequent p-doped gallium nitride layer, and the like).

FIG. 2D is a schematic illustration of a member, in accordance with yet another embodiment of the present disclosure. FIG. 2D is described in conjunction with elements from the FIGS. 1A, 1B, 2A, 2B and 2C. With reference to FIG. 2D, there is shown a schematic illustration of a member 200D that includes the silicon base substrate layer 102 (not shown in FIG. 2D), the transition layer 104 (not shown in FIG. 2D), the gallium nitride buffer layer 106, the first gallium nitride channel layer 108A, and the second gallium nitride channel layer 108B. The member 200D further includes the first aluminium gallium nitride barrier layer 110A, the second aluminium gallium nitride barrier layer 110B, the first p-doped gallium nitride layer 112A, the second p-doped gallium nitride layer 112B, and the passivation layer 202.

In an implementation, a recess is formed at each end of the member 200C of FIG. 2C, such as at a left end, as well as at a right end, which results in the formation of the member 200D of FIG. 2D. As a result, the first aluminium gallium nitride barrier layer 110A is exposed from a top view of the member 200D, and at both ends of the member 200D, as shown in FIG. 2D. The exposed area of the first aluminium gallium nitride barrier layer 110A is beneficial for a selective arrangement of metal contacts, such as the source contact 116 (of FIG. 1A and 1B), and the drain contact (of FIG. 1A and 1B).

In another implementation, the recess is formed at both ends of the member 200C so as to etch away completely the first aluminium gallium nitride barrier layer 110A, due to which the gallium nitride buffer layer 106 will be exposed though the recess. The exposed area of the gallium nitride buffer layer 106 is beneficial for a selective arrangement of metal contacts, such as the source contact 116 (of FIGS. 1A and 1B), and the drain contact (of FIGS. 1A and 1B) over the gallium nitride buffer layer 106.

FIG. 2E is a schematic illustration of a member, in accordance with another embodiment of the present disclosure. FIG. 2E is described in conjunction with elements from the FIGS. 1A, 1B, 2A, 2B, 2C and 2D. With reference to FIG. 2E, there is shown a schematic illustration of a member 200E that includes the gallium nitride buffer layer 106, the first gallium nitride channel layer 108A, and the second gallium nitride channel layer 108B. The member 200E further includes the first aluminium gallium nitride barrier layer 110A, the second aluminium gallium nitride barrier layer 110B, the first p-doped gallium nitride layer 112A, the second p-doped gallium nitride layer 112B, and the passivation layer 202.

In an implementation, the passivation layer 202 is arranged at the top of the second p-doped gallium nitride layer 112B of the member 200E. In addition, the passivation layer 202 is also arranged at side surfaces (e.g., left side and right side) of the second p-doped gallium nitride layer 112B, the second aluminium gallium nitride barrier layer 110B, the second gallium nitride channel layer 108B, and the first p-doped gallium nitride layer 112A. Therefore, the passivation layer 202 arranged on the member 200E is beneficial to prevent the oxidation of the second p-doped gallium nitride layer 112B from the top as well as from both sides. The passivation layer 202 further prevent the oxidation of the side surfaces of the second aluminium gallium nitride barrier layer 110B, the second gallium nitride channel layer 108B, and the first p-doped gallium nitride layer 112A. The passivation layer 202 further reduces any possible leakage paths from the stacked layers to the source contact 116 (or drain contact 118.

FIG. 2F is a schematic illustration of a member, in accordance with yet another embodiment of the present disclosure. FIG. 2F is described in conjunction with elements from the FIGS. 1A, 1B, 2A, 2B, 2C, 2D and 2E. With reference to FIG. 2F, there is shown a schematic illustration of a member 200F that includes the gallium nitride buffer layer 106, the first gallium nitride channel layer 108A, and the second gallium nitride channel layer 108B. The member 200F further includes the first aluminium gallium nitride barrier layer 110A, the second aluminium gallium nitride barrier layer 110B, the first p-doped gallium nitride layer 112A, the second p-doped gallium nitride layer 112B, and the passivation layer 202. The member 200F further includes the gate contact 114, the source contact 116, and the drain contact 118. The member 200F may also include the silicon base substrate layer 102 and the transition layer 104 (not shown in FIG. 2F).

In an implementation, the source contact 116 is arranged on a left end of an exposed area of the first aluminium gallium nitride barrier layer 110A (i.e., on the left end of the member 200D of FIG. 2D). Moreover, the drain contact 118 is arranged on a right end of the exposed area of the first aluminium gallium nitride barrier layer 110A (i.e., on a right end of the member 200D of FIG. 2D). Furthermore, the gate contact 114 is arranged on the connecting p-doped gallium nitride portion 120 (i.e., of FIG. 2D). As a result, the member 200F includes three metal contacts, such as the gate contact 114, the source contact 116, and the drain contact 118, which are beneficial for further connection purposes (e.g., to provide supply to the member 200F).

In an implementation, the source contact 116, and the drain contact 118 form an ohmic contact with a two-dimensional electron gas, which is positioned at an interface between the first aluminium gallium nitride barrier layer 110A, and the first gallium nitride channel layer 108A. In addition, the source contact 116, and the drain contact 118 are also laterally in contact with another two-dimensional electron gas (which is positioned at an interface between the second aluminium gallium nitride barrier layer 110B, and the second gallium nitride channel layer 108B), and with the second p-doped gallium nitride layer 112B.

FIG. 2G is a schematic illustration of a member, in accordance with another embodiment of the present disclosure. FIG. 2G is described in conjunction with elements from the FIGS. 1A, 1B, 2A, 2B, 2C, 2D, 2E and 2F. With reference to FIG. 2G, there is shown a schematic illustration of a member 200G that includes the gallium nitride buffer layer 106, the first gallium nitride channel layer 108A, and the second gallium nitride channel layer 108B. The member 200G further includes the first aluminium gallium nitride barrier layer 110A, the second aluminium gallium nitride barrier layer 110B, the first p-doped gallium nitride layer 112A, the second p-doped gallium nitride layer 112B, and the passivation layer 202. The member 200G further includes the gate contact 114, the source contact 116, and the drain contact 118.

In accordance with an embodiment, the passivation layer 202 extends between the source contact 116 and the first p-doped gallium nitride (pGaN) layer 112A and between the drain contact 118 and the first p-doped gallium nitride (pGaN) layer 112A. In other words, the source contact 116 is arranged on a left end of an exposed area of the first aluminium gallium nitride barrier layer 110A (i.e., on a left end of the member 200E of FIG. 2E). Moreover, the drain contact 118 is arranged on a right end of the exposed area of the first aluminium gallium nitride barrier layer 110A (i.e., on a right end of the member 200E of FIG. 2E). Furthermore, the gate contact 114 is arranged on the connecting p-doped gallium nitride portion 120 (i.e., of FIG. 2E). As a result, the passivation layer 202 extends between the source contact 116 and the first p-doped gallium nitride layer 112A, and also between the drain contact 118 and the first p-doped gallium nitride layer 112A of the member 200G. The passivation layer 202 is beneficial to provide lateral isolation between the source contact 116, and the first p-doped gallium nitride layer 112A, and also between the drain contact 118 and the first p-doped gallium nitride layer 112A. Moreover, the passivation layer 202 reduces all possible leakage paths, especially at high voltage.

In accordance with an embodiment, the passivation layer 202 comprises aluminium oxide, aluminium nitride, silicon dioxide or silicon nitride. Therefore, the passivation layer 202 provides an improved isolation between the source contact 116 and the first p-doped gallium nitride layer 112A, and also between the drain contact 118 and the first p-doped gallium nitride layer 112A. In an example, the passivation layer 202 further provides isolation between the source contact 116 and the second p-doped gallium nitride layer 112B, the second aluminium gallium nitride barrier layer 110B, the second gallium nitride channel layer 108B, along with the first p-doped gallium nitride layer 112A. The passivation layer 202 further provides isolation between the drain contact 118 and the second p-doped gallium nitride layer 112B, the second aluminium gallium nitride barrier layer 110B, the second gallium nitride channel layer 108B, along with the first p-doped gallium nitride layer 112A, as shown in FIG. 2G.

FIG. 3 is a schematic illustration of a member, in accordance with another embodiment of the present disclosure. FIG. 3 is described in conjunction with elements from the FIGS. 1A, 1B, and 2A to 2G. With reference to FIG. 3, there is shown a schematic illustration of a member 300 that includes a two-dimensional electron gas (2DEG) 302. The member 300 further includes the gallium nitride buffer layer 106, the first gallium nitride channel layer 108A, and the second gallium nitride channel layer 108B. The member 300 further includes the first aluminium gallium nitride barrier layer 110A, the second aluminium gallium nitride barrier layer 110B, the first p-doped gallium nitride layer 112A, and the second p-doped gallium nitride layer 112B.

The two-dimensional electron gas 302 is a scientific model in solid-state physics, where the two-dimensional electron gas is free to move in two dimensions, but tightly confined in a third dimension. Moreover, such tight confinement leads to quantized energy levels for the motion of the two-dimensional electron gas in the third dimension, which can then be ignored for most problems. Thus, the two-dimensional electron gas appears to be a two-dimensional (2D) sheet embedded in a three-dimensional (3D) world.

In an implementation, the member 300 includes a contemporary use of the two-dimensional electron gas 302 that is formed at an interface between the first aluminium gallium nitride barrier layer 110A and the first gallium nitride channel layer 108A. In addition, two-dimensional electron gas 302 is also formed between the second aluminium gallium nitride barrier layer 110B, and the second gallium nitride channel layer 108B. Beneficially, by virtue of using the two-dimensional electron gas 302, the member 300 is less prone to dynamic effects due to surface defects, and also to thickness variation caused by process variations (e.g., etching of p-doped gallium nitride).

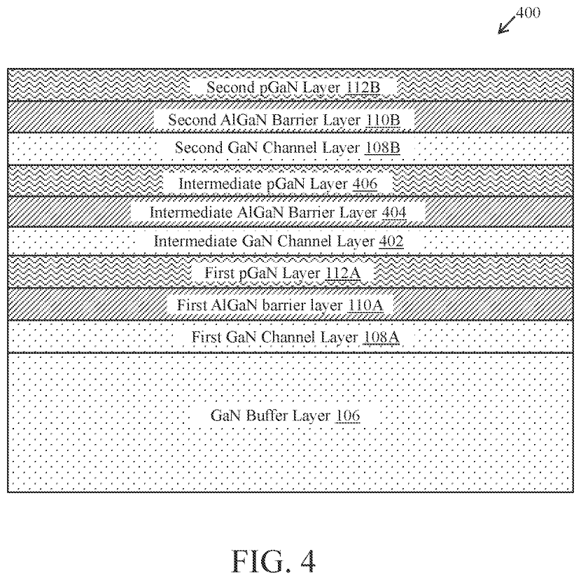

FIG. 4 is a schematic illustration of a member, in accordance with yet another embodiment of the present disclosure. FIG. 4 is described in conjunction with elements from the FIGS. 1A, 1B, 2A to 2G, and 3. With reference to FIG. 4, there is shown a schematic illustration of a member 400 that includes at least one intermediate gallium nitride (GaN) channel layer 402, at least one intermediate aluminium gallium nitride (AlGaN) barrier layer 404, and at least one intermediate p-doped gallium nitride (pGaN) layer 406. The member 400 further includes the gallium nitride buffer layer 106, the first gallium nitride channel layer 108A, and the second gallium nitride channel layer 108B. The member 300 further includes the first aluminium gallium nitride barrier layer 110A, the second aluminium gallium nitride barrier layer 110B, the first p-doped gallium nitride layer 112A, and the second p-doped gallium nitride layer 112B.

In accordance with an embodiment, the member 400 further comprises at least one intermediate gallium nitride (GaN) channel layer 402. The member 400 further comprises at least one intermediate aluminium gallium nitride (AlGaN) barrier layer 404 arranged over the at least one intermediate gallium nitride (GaN) channel layer 402 and at least one intermediate p-doped gallium nitride (pGaN) layer 406 arranged over the at least one intermediate aluminium gallium nitride (AlGaN) barrier layer 404 respectively. The at least one intermediate gallium nitride (GaN) channel layer 402, the at least one intermediate aluminium gallium nitride (AlGaN) barrier layer 404 and the at least one intermediate p-doped gallium nitride (pGaN) layer 406 are arranged between the first gallium nitride (GaN) channel layer 108A, the first aluminium gallium nitride (AlGaN) barrier layer 110A, the first p-doped gallium nitride (pGaN) layer 112A and the second gallium nitride (GaN) channel layer 108B, the second aluminium gallium nitride (AlGaN) barrier layer 110B, the second p-doped gallium nitride (pGaN) layer 112B. In other words, the member 400 further includes at least one intermediate epitaxial stack layer, which further includes a batch of three layers, such as the at least one intermediate gallium nitride channel layer 402, the at least one intermediate aluminium gallium nitride barrier layer 404, and the at least one intermediate p-doped gallium nitride layer 406. The at least one intermediate gallium nitride channel layer 402 of the member 400 is arranged over the first p-doped gallium nitride layer 112A, and the at least one intermediate aluminium gallium nitride barrier layer 404 is arranged over the at least one intermediate gallium nitride channel layer 402. In addition, the at least one intermediate p-doped gallium nitride layer 406 is arranged over the at least one intermediate aluminium gallium nitride barrier layer 404. Therefore, the member 400 includes the at least one intermediate epitaxial stack layer that is arranged over the first epitaxial stack layer. In an example, doping degree, as well as dimensions of each layer of the at least one intermediate epitaxial stack layer, are beneficial to achieve the desired performance as well as the desired reliability.

The member 400 further includes the second epitaxial stack layer, which is arranged over the at least one intermediate epitaxial stack layer. For example, the second gallium nitride channel layer 108B of the second epitaxial stack layer is arranged over the at least one intermediate p-doped gallium nitride layer 406 of the at least one intermediate epitaxial stack layer. Thereafter, the second aluminium gallium nitride barrier layer 110B is arranged over the second gallium nitride channel layer 108B, and the second p-doped gallium nitride layer 112B is arranged over the second aluminium gallium nitride barrier layer 110B. By virtue of using the at least one intermediate gallium nitride channel layer 402, the at least one intermediate aluminium gallium nitride barrier layer 404, and the at least one intermediate p-doped gallium nitride layer 406, the member 400 achieves an improved reliability.

In an implementation, the member 400 includes a contemporary use of the two-dimensional electron gas 302 (of FIG. 3) that is formed at an interface between the at least one intermediate aluminium gallium nitride barrier layer 404, and the at least one intermediate gallium nitride channel layer 402. By virtue of using the two-dimensional electron gas 302, the member 400 is less prone to dynamic effects due to surface defects, and also to thickness variation caused by process variations.

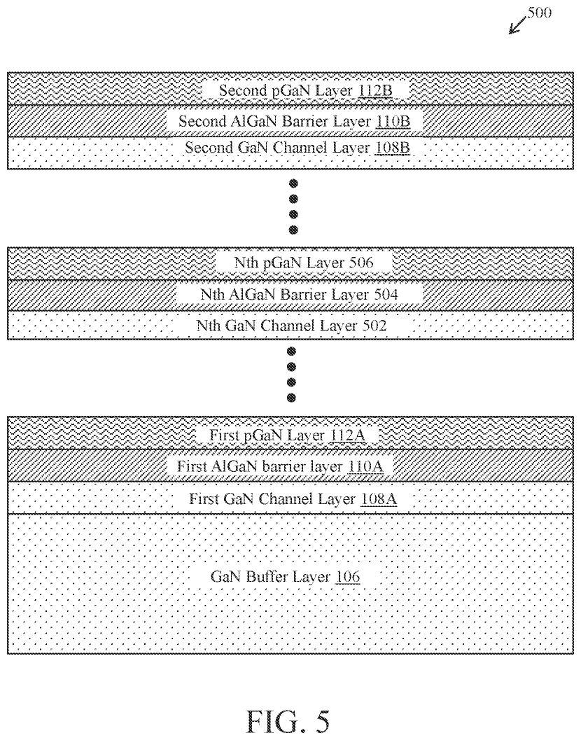

FIG. 5 is a schematic illustration of a member, in accordance with another embodiment of the present disclosure. FIG. 5 is described in conjunction with elements from the FIGS. 1A, 1B, 2A to 2G, 3 and 4. With reference to FIG. 5, there is shown a schematic illustration of a member 500 that includes N^{th} gallium nitride (GaN) channel layer 502, N^{th} aluminium gallium nitride (AlGaN) barrier layer 504, and N^{th} p-doped gallium nitride (pGaN) layer 506. The member 500 further includes the silicon base substrate layer 102 (not shown in FIG. 3), the transition layer 104 (not shown in FIG. 3), the gallium nitride buffer layer 106, the first gallium nitride channel layer 108A, and the second gallium nitride channel layer 108B. The member 500 further includes the first aluminium gallium nitride barrier layer 110A, the second aluminium gallium nitride barrier layer 110B, the first p-doped gallium nitride layer 112A, and the second p-doped gallium nitride layer 112B.

In an implementation, the member 500 further includes N^{th} intermediate epitaxial stack layer, which further includes the N^{th} gallium nitride channel layer 502, the N^{th} aluminium gallium nitride barrier layer 504, and the N^{th} p-doped gallium nitride layer 506. For example, the N^{th} intermediate epitaxial stack layer is arranged between the first epitaxial stack layer and the second epitaxial stack layer, as shown in FIG. 5. In an example, doping degree, as well as dimensions of each layer of the N^{th} intermediate epitaxial stack layer, are beneficial to achieve the desired performance as well as the desired reliability. By virtue of using the N^{th} gallium nitride channel layer 502, the N^{th} aluminium gallium nitride barrier layer 504, and the N^{th} p-doped gallium nitride layer 506, the member 500 achieves an improved reliability. In an example, the member 500 includes a contemporary use of the two-dimensional electron gas 302 (of FIG. 3) that is formed at an interface between the N^{th} aluminium gallium nitride barrier layer 504, and the N^{th} gallium nitride channel layer 502. By virtue of using the two-dimensional electron gas 302, the member 500 is less prone to dynamic effects due to surface defects, and also to thickness variation caused by process variations.

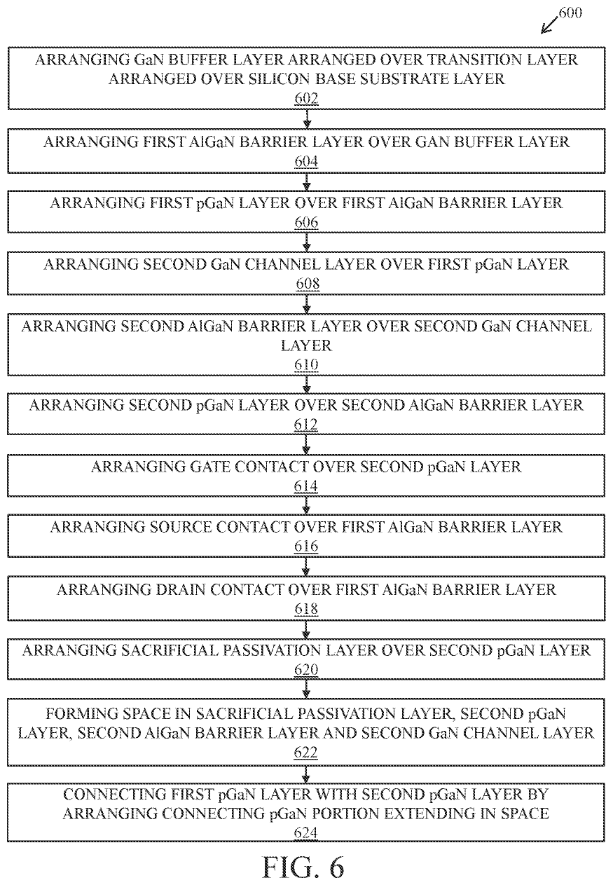

FIG. 6 is a flowchart of an exemplary method for an exemplary manufacturing a member, in accordance with an embodiment of the present disclosure. FIG. 6 is described in conjunction with elements from FIGS. 1A, 1B, 2A to 2G, 3, 4 and 5. With reference to FIG. 6, there is shown a method 600 that includes steps 602 and 624.

In another aspect, the present disclosure provides a method 600 for manufacturing a member 100A. The method 600 implies the use of at least two aluminium gallium nitride layers so as to increase the reliability of the member 100A. The method 600 is applicable to all of the members 100A, 100B, 200A, 200B, 200C, 200D, 200E, 200F, 200G, 300,400 and 500.

At step 602, the method 600 comprises arranging a gallium nitride (GaN) buffer layer 106 arranged over a transition layer 104 arranged over a silicon base substrate layer 102. In other words, the method 600 comprises arranging the silicon base substrate layer 102, which is acting as a base of the member 100A. Thereafter, the method 600 comprises, depositing the transition layer 104 on the silicon base substrate layer 102, and then depositing the gallium nitride buffer layer 106 on the transition layer 104. As a result, the member 100A includes the silicon base substrate layer 102, the transition layer 104, and the gallium nitride buffer layer 106 (e.g., such as forming a GaN-On-Si substrate). Beneficially, the transition layer 104 provides sufficient strain relief and also limits (or prevents) the formation of cracks in the gallium nitride buffer layer 106.

At step 604, the method 600 comprises arranging a first aluminium gallium nitride (AlGaN) barrier layer 110A over the gallium nitride (GaN) buffer layer 106. As the first aluminium gallium nitride barrier layer 110A is arranged over the gallium nitride buffer layer 106. Thus, the member 100A makes use of the properties of the gallium nitride buffer layer 106 to achieve higher electrical performance, for example, breakdown voltage (BV) for different semiconductor devices. In an implementation, the method 600 comprises, forming the first gallium nitride channel layer 108A from a portion of the gallium nitride buffer layer 106, where the first gallium nitride channel layer 108A is in direct contact with the gallium nitride buffer layer 106. In such implementation, the first aluminium gallium nitride barrier layer 110A is arranged on the first gallium nitride channel layer 108A.

At step 606, the method 600 comprises arranging a first p-doped gallium nitride (pGaN) layer 112A over the first aluminium gallium nitride (AlGaN) barrier layer 110A. Therefore, method 600 provides a new device concept that makes use of a stacked layer approach in the member 100A, and as well as the use of p-type doped gallium nitride, such as the first p-doped gallium nitride layer 112A. As a result, the member 100A includes a first epitaxial stack that includes a batch of three layers, such as the first gallium nitride channel layer 108A, the first aluminium gallium nitride barrier layer 110A, and the first p-doped gallium nitride layer 112A.

At step 608, the method 600 comprises arranging a second gallium nitride (GaN) channel layer 108B over the first p-doped gallium nitride (pGaN) layer 112A. Therefore, the method 600 is beneficial to co-integrate the first p-doped gallium nitride layer 112A with the second gallium nitride (GaN) channel layer 108B.

At step 610, the method comprises arranging a second aluminium gallium nitride (AlGaN) barrier layer 110B over the second gallium nitride (GaN) channel layer 108B. By virtue of arranging the second aluminium gallium nitride barrier layer 110B over the second gallium nitride channel layer 108B, the method 600 achieves an electric field distribution along the second aluminium gallium nitride barrier layer 110B. In an implementation, the method 600 comprises a contemporary use of the two-dimensional electron gas that forms at an interface between the second aluminium gallium nitride barrier layer 110B, and the second gallium nitride channel layer 108B. As a result, the member 100A achieves enhanced high voltage operation capability.

At step 612, the method comprises arranging a second p-doped gallium nitride (pGaN) layer 112B over the second aluminium gallium nitride (AlGaN) barrier layer 110B. Beneficially, the member 100A makes use of the p-type doping capability of gallium nitride technology, such as by arranging the second p-doped gallium nitride (pGaN) layer 112B over the second aluminium gallium nitride (AlGaN) barrier layer 110B. In an example, the doping degree for the second p-doped gallium nitride layer 112B has a p-type concentration between 1e¹⁷ cubic centimetres (cm⁻³) and 5e¹⁸ cubic cm⁻³. As a result, the member 100 includes a second epitaxial stack that includes a batch of three layers, such as the second gallium nitride channel layer 108B, the second aluminium gallium nitride barrier layer 110B, and the second p-doped gallium nitride layer 112B. Moreover, the second epitaxial stack is arranged over the first epitaxial stack.

At step 614, the method 600 comprises arranging a gate contact 114 over the second p-doped gallium nitride (pGaN) layer 112B. The gate contact 114 arranged over second p-doped gallium nitride (pGaN) layer 112B is beneficial for further connections (e.g., for electrical supply purposes). In an example, the gate contact is arranged over the connecting p-doped gallium nitride portion 120. The connecting p-doped gallium nitride portion 120 is beneficial to deplete a two-dimensional electron gas below the gate contact 114 and also to allow a normally-off device operation of the member 100A.

At step 616, the method comprises arranging a source contact 116 over the first aluminium gallium nitride (AlGaN) barrier layer 110A. The source contact 116 arranged over the first aluminium gallium nitride barrier layer 110A is beneficial for further connections (e.g., for electrical supply purposes).

At step 618, the method comprises arranging a drain contact 118 over the first aluminium gallium nitride (AlGaN) barrier layer 110A. The drain contact 118 arranged over the first aluminium gallium nitride barrier layer 110A is beneficial for further connections (e.g., for electrical supply purposes). The method 600 of the present disclosure allows a drastic reduction in an electric field peak at an edge of the gate contact 114 and the drain contact 118 (or at the gate-drain edge).

At step 620, the method 600 comprises arranging a sacrificial passivation layer over the second p-doped gallium nitride (pGaN) layer 112B. The sacrificial passivation layer (or the passivation layer 202 of FIG. 2A) is beneficial to prevent oxidation of the second p-doped gallium nitride layer 112B.

At step 622, the method 600 comprises forming a space 304 in the sacrificial passivation layer, the second p-doped gallium nitride (pGaN) layer 112B, the second aluminium gallium nitride (AlGaN) barrier layer 110B and the second gallium nitride (GaN) channel layer 108B. In an implementation, the method 600 comprises, forming the space 304, such as by removing the sacrificial passivation layer from one point along with the second p-doped gallium nitride layer 112B, the second aluminium gallium nitride barrier layer 110B and the second gallium nitride (GaN) channel layer 108B. As a result, the first p-doped gallium nitride layer 112A is exposed through the space 204. The space 304 is beneficial for a selective arrangement of the connecting p-doped gallium nitride portion 120.

At step 624, the method 600 comprises connecting the first p-doped gallium nitride (pGaN) layer 112A with the second p-doped gallium nitride (pGaN) layer 112B by arranging a connecting p-doped gallium nitride (pGaN) portion 120 extending in the space 204. In other words, the method 600 comprises, arranging the connecting p-doped gallium nitride portion 120 within the space 204, and also over the first p-doped gallium nitride layer 112A. Therefore, selective placement of the connecting p-doped gallium nitride portion 120 is performed on the first p-doped gallium nitride layer 112A. Moreover, the connecting p-doped gallium nitride portion 120 is in direct contact with the first p-doped gallium nitride layer 112A, and also with the second p-doped gallium nitride layer 112B. In an example, the connecting p-doped gallium nitride portion 120 also has a doping degree that ranges between 1e¹⁸ cm⁻³ and 5e¹⁹ cm⁻³.

The method 600 of the present disclosure allows a drastic reduction in an electric field peak at an edge of the gate contact 114 and the drain contact 118 (or at gate-drain edge). Moreover, due to the use of the second aluminium gallium nitride barrier layer 110B, there exists a flat electric field distribution along the first aluminium gallium nitride barrier layer 110A (and the second aluminium gallium nitride barrier layer 110B). In addition, the method 600 is beneficial for achieving an improved breakdown voltage (BV), which allows having a drastic reduction in a semiconductor device dimensions for the same target breakdown voltage. The method 600 is also beneficial for improving the reliability of the semiconductor device without sacrificing the overall performance of the semiconductor device.

In accordance with an embodiment, the method 600 further comprises arranging the source contact 116 and the drain contact 118 by arranging a recess in the second aluminium gallium nitride (AlGaN) barrier layer 110B, the second p-doped gallium nitride (pGaN) layer 112B the second gallium nitride (GaN) channel layer 108B, and the first p-doped gallium nitride (pGaN) layer 112A. In an implementation, the method 600 comprises, arranging the recess (e.g., via etching) at each end of the member 100A, such as at a left end as well as at a right end of the member 100A. In an example, arranging the recess corresponds to making an opening in the second aluminium gallium nitride barrier layer 110B, the second p-doped gallium nitride layer 112B the second gallium nitride channel layer 108B, and the first p-doped gallium nitride layer 112A. As a result, the first aluminium gallium nitride barrier layer 110A is exposed from a top view of the member 100A (e.g., exposed or visible at both ends of the member 100A). Thereafter, the source contact 116 is arranged one end (e.g., left end) of the first aluminium gallium nitride barrier layer 110A, and the drain contact 118 is arranged at another end (e.g., right end) of the first aluminium gallium nitride barrier layer 110A. As a result, the first p-doped gallium nitride layer 112A is arranged between the source contact 116 and the drain contact 118.

In an implementation, the method 600 further comprises arranging the source contact 116 and the drain contact 118 by arranging a recess in the second aluminium gallium nitride (AlGaN) barrier layer 110B, the second p-doped gallium nitride (pGaN) layer 112B the second gallium nitride (GaN) channel layer 108B, the first p-doped gallium nitride (pGaN) layer 112A, the first aluminium gallium nitride (AlGaN) barrier layer 110A, and the gallium nitride (GaN) channel layer 108A. In this case, the source contact 116 and the drain contact 118 are in direct contact with the GaN buffer layer 106.

In an implementation, the source contact 116, and the drain contact 118 form an ohmic-like contact with a two-dimensional electron gas, which is positioned at an interface between the first aluminium gallium nitride barrier layer 110A, and the first gallium nitride channel layer 108A. In addition, the source contact 116, and the drain contact 118 are also laterally in contact with another two-dimensional electron gas (which is positioned at an interface between the second aluminium gallium nitride barrier layer 110B, and the second gallium nitride channel layer 108B), and with the second p-doped gallium nitride layer 112B.

In accordance with another embodiment, the method 600 further comprises manufacturing a member 100A. By virtue of manufacturing the member 100A, using the method 600, there exists a flat electric field distribution along the first aluminium gallium nitride barrier layer 110A (and the second aluminium gallium nitride barrier layer 110B) of the member 100A. The method 600 is beneficial for improving the reliability of a semiconductor device without sacrificing the overall performance of the semiconductor device.

The steps 602 to 624 are only illustrative, and other alternatives can also be provided where one or more steps are added, one or more steps are removed, or one or more steps are provided in a different sequence without departing from the scope of the claims herein. For example, in some implementations, the step 614 may be executed after the step 616 and 618. Alternatively, the step 616 and 618 may be executed in parallel or the sequence of execution may change without limiting the scope of the disclosure.

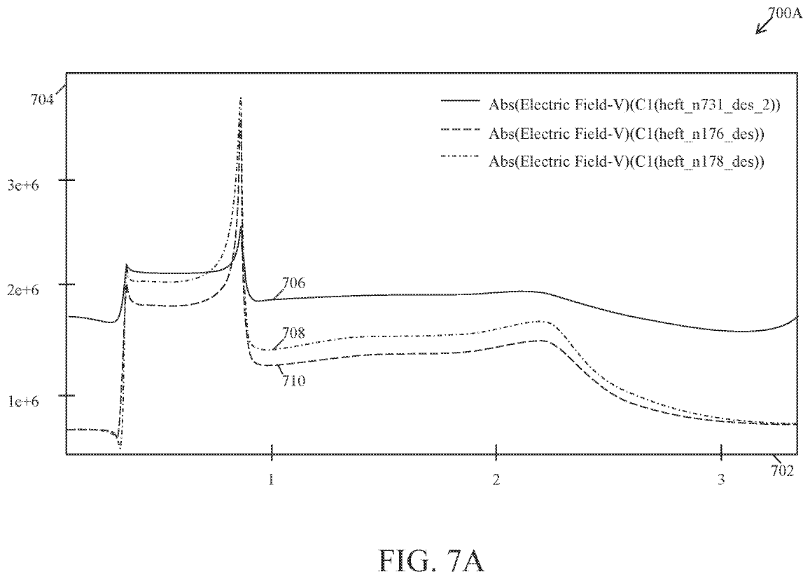

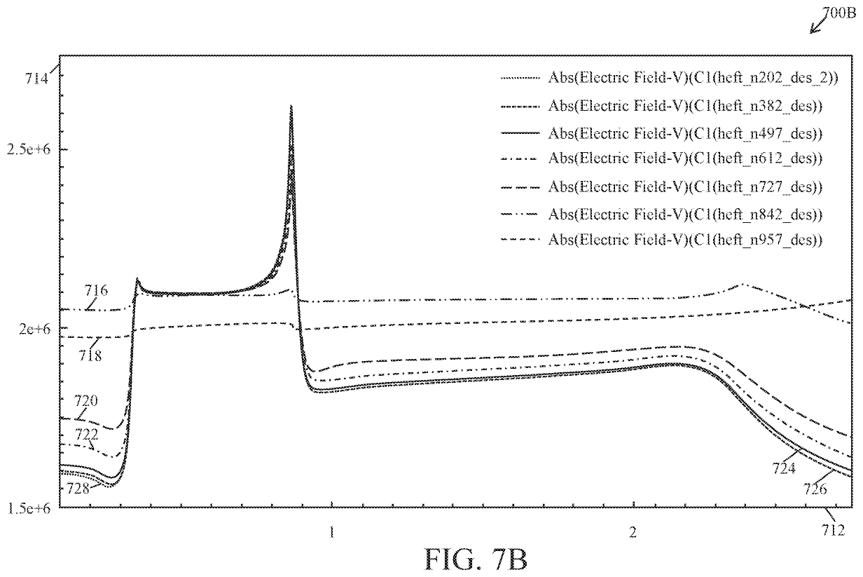

FIG. 7A is a graphical representation that illustrates an electric field cut along a direction of a gallium nitride channel layer within an aluminium gallium nitride barrier layer, during off-state conditions, in accordance with an embodiment of the present disclosure. FIG. 7A is described in conjunction with elements from FIGS. 1A, 1B, 2A to 2G, 3, 4 and 5. With reference to FIG. 7A, there is shown a graphical representation 700A that illustrates an electric field cut along a direction of a gallium nitride channel layer within an aluminium gallium nitride barrier, during off-state conditions.

The graphical representation 700A represents arbitrary units on the X-axis 702 and the electric field on the Y-axis 704. In the graphical representation, the lines 708 and 710 illustrate electric field cut along direction of the gallium nitride channel layer within an aluminium gallium nitride barrier layer, during off-state conditions of a conventional approach. In particular, the line 706 illustrates the electric field cut along the direction of the gallium nitride channel layer within the aluminium gallium nitride barrier layer, during off-state conditions for the member 100A of the present disclosure. For example, the electric field cut along the direction of the first gallium nitride channel layer 108A within the first aluminium gallium nitride barrier layer 110A. Similarly, the electric field cut along a direction of the second gallium nitride channel layer 108B within the first aluminium gallium nitride barrier layer 110A, during off-state conditions for the member 100A. The line 706 illustrates that the member 100A allows a massive reduction of the peak electric field in the second aluminium gallium nitride barrier layer 110B. This, in turn, enables the member 100A to significantly improve the overall device reliability of a semiconductor device.

FIG. 7B is a graphical representation that illustrates an electric field cut along a direction of a gallium nitride channel layer within an aluminium gallium nitride barrier layer, during off-state conditions, for different p-type doping degrees in the p-doped gallium nitride layer, in accordance with an embodiment of the present disclosure. FIG. 7B is described in conjunction with elements from FIGS. 1A, 1B, 2A to 2G, 3, 4 and 5. With reference to FIG. 7B, there is shown a graphical representation 700B that illustrates an electric field cut along a direction of a gallium nitride channel layer within an aluminium gallium nitride barrier layer, during off-state conditions, for different p-type doping degrees in a p-doped gallium nitride layer of the member 100A.

The graphical representation 700B represents arbitrary units on the X-axis 712 and the electric field on the Y-axis 714. In particular, the lines 716, 718, 720, 722, 724, 726, and 728 illustrates the electric field cut along direction of the gallium nitride channel layer within an aluminium gallium nitride barrier layer, during off-state conditions, for different p-type doping degree in the p-doped gallium nitride layer of the member 100A. For example, the electric field cut along the direction of the first gallium nitride channel layer 108A within the first aluminium gallium nitride barrier layer 110A, during off-state conditions, and for different p-type doping in the first p-doped gallium nitride layer 112A of the member 100A. Similarly, the electric field cut along the direction of the second gallium nitride channel layer 108B within the second aluminium gallium nitride barrier layer 110B, during off-state conditions, for different p-type doping degrees in the second p-doped gallium nitride layer 112B of the member 100A.

The lines 716, 718, 720, 722, 724, 726, and 728 illustrates a uniform doping concentration ranging from 1e¹⁶ cm⁻³ up to 5e¹⁸ cm⁻³. As visible from the lines 716, 718, 720, 722, 724, 726, and 728, when the p-type doping degree reaches a certain threshold, where compensation between the p-type and n-type carrier occurs. Then, a very flat electric field profile is obtained without any sharp peak at an interface of the aluminium gallium nitride barrier layer, and the gallium nitride channel layer. For example, at the interface of the first aluminium gallium nitride barrier layer 110A and the first gallium nitride channel layer 108A, and also at the interface of the second aluminium gallium nitride barrier layer 110B and the second gallium nitride channel layer 108B. As a result, different p-type doping degrees allows to greatly improve the overall reliability of the member 100A and also boost the breakdown strength of the member 100A.

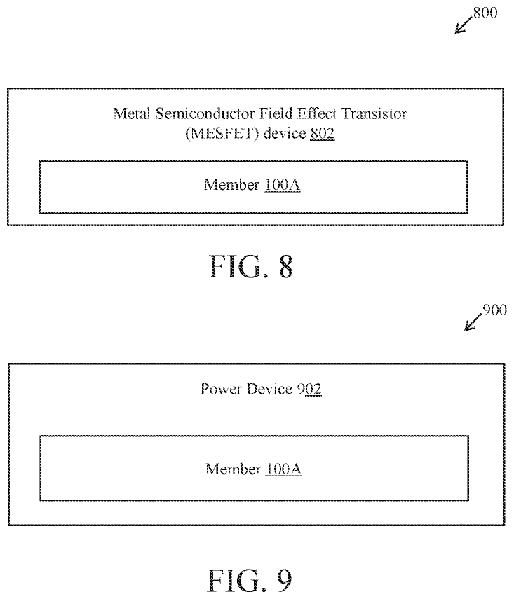

FIG. 8 is a block diagram of a metal-semiconductor field-effect transistor (MESFET) device, in accordance with an embodiment of the present disclosure. FIG. 8 is described in conjunction with elements from FIGS. 1A, 1B, 2A to 2G, 3, 4 and 5. With reference to FIG. 8, there is shown a block diagram 800 of a metal-semiconductor field-effect transistor (MESFET) device 802 that includes the member 100A.

The MESFET device 802 is a semiconductor device, which is generally used to amplify or switch electronic signals. The MESFET device 802 is one of the basic building blocks of modern electronics. The MESFET device 802 is composed of semiconductor material.

In another aspect, the present disclosure provides a metal-semiconductor field-effect transistor (MESFET) device 802 comprising a member 100A. By virtue of using the member 100A, the MESFET device 802 achieves a very flat electric field profile, an improved reliability as well as improved breakdown strength.

FIG. 9 is a block diagram of a power device, in accordance with an embodiment of the present disclosure. FIG. 9 is described in conjunction with elements from FIGS. 1A, 1B, 2A to 2G, 3, 4 and 5. With reference to FIG. 9, there is shown a block diagram 900 of a power device 902 that includes the member 100A.

The power device 902 is a semiconductor device that is used as a switch or rectifier in power electronics, such as in an integrated circuit or a power integrated circuit. Examples of the power device 902 include but are not limited to a power diode, a thyristor, an insulated-gate bipolar transistor (IGBT), and the like.

In yet another aspect, the present disclosure provides a power device 902 comprising the member 100A. By virtue of using the member 100A, the power device 902 achieves a very flat electric field profile, an improved reliability as well as an improved breakdown strength. The power device 902 (or gallium nitride power filed effect transistor) achieves an enhanced high voltage operation.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the invention, which are, for brevity, described in the context of a single embodiment, may also be provided separately or in any suitable combination or as suitable in any other described embodiment of the disclosure.

1. A member, comprising:
a silicon base substrate layer;
a transition layer arranged over the silicon base substrate layer;
a gallium nitride (GaN) buffer layer arranged over the transition layer, a first aluminum gallium nitride (AlGaN) barrier layer arranged over the gallium nitride (GaN) buffer layer;
a first p-doped gallium nitride (pGaN) layer arranged over the first AlGaN barrier layer, wherein a portion of the GaN buffer layer forms a first GaN channel layer, and wherein the first GaN channel layer, the first AlGaN barrier layer, and the first pGaN layer form a first epitaxial stack;
a second GaN channel layer arranged over the first pGaN layer;
a second AlGaN barrier layer arranged over the second GaN channel layer;
a second pGaN layer arranged over the second AlGaN barrier layer;
a gate contact arranged over the second pGaN layer;
a source contact arranged over the first AlGaN barrier layer; and
a drain contact arranged over the first AlGaN barrier layer, wherein the second pGaN layer is connected to the first pGaN layer by a connecting pGaN portion extending through a space in the second AlGaN barrier layer (and the second GaN channel layer, and wherein the first pGaN layer is arranged between the source contact and the drain contact.

2. The member according to claim 1, wherein the gate contact is arranged over the connecting pGaN portion.

3. The member according to claim 2, wherein the connecting pGaN portion connecting the first pGaN layer and the second pGaN layer is arranged to extend above an upper surface of the second pGaN layer.

4. The member according to claim 1, wherein:
the first GaN channel layer has a first GaN channel layer thickness;
the first AlGaN barrier layer (has a first AlGaN barrier layer thickness;
the first pGaN layer has a first pGaN layer thickness;
the second GaN channel layer has a second GaN channel layer thickness;
the second AlGaN barrier layer has a second AlGaN barrier layer thickness;
the second pGaN layer has a second pGaN layer thickness; and wherein at least one of the following factors is present:
the second GaN channel layer thickness equals the first GaN channel layer thickness;
the second AlGaN barrier layer thickness equals the first AlGaN barrier layer thickness; or
the second ppGaN layer thickness equals the first pGaN layer thickness.

5. The member according to claim 1, wherein:
the first GaN channel layer (has a first GaN channel layer thickness;
the first AlGaN barrier layer has a first AlGaN barrier layer thickness;
the first pGaN layer has a first pGaN layer thickness;
the second GaN channel layer has a second GaN channel layer thickness;
the second AlGaN barrier layer has a second AlGaN barrier layer thickness;
the second pGaN layer has a second pGaN layer thickness; and wherein at least one of the following factors is present:
the second GaN channel layer thickness differs from the first GaN channel layer thickness;
the second AlGaN barrier layer thickness differs from the first AlGaN barrier layer thickness;
the second pGaN layer thickness differs from the first pGaN layer thickness.

6. The member according to claim 4, wherein at least one of the following factors is present:
the first GaN channel layer thickness is in a first range;
the first AlGaN barrier layer thickness is in a second range;
the first p-doped pGaN layer thickness is in a third range;
the second GaN channel layer thickness is in a fourth range;
the second AlGaN barrier layer thickness is in a fifth range; or
the second pGaN layer thickness is in a sixth range.

7. The member according to claim 1, wherein at least one of the following factors is present:
the first GaN channel layer has a doping degree in a first range;
the first AlGaN barrier layer has a doping degree in a second range;
the first pGaN layer has a doping degree in a third range;
the second GaN channel layer has a doping degree in a fourth range;
the second AlGaN barrier layer has a doping degree in a fifth range; or
the second pGaN layer has a doping degree in a sixth range.

8. The member according to claim 1, wherein the member further comprises a passivation layer arranged over the second pGaN layer, and wherein the connecting pGaN portion extends through the passivation layer.

9. The member according to claim 8, wherein the passivation layer extends between the source contact and the first pGaN layer and between the drain contact and the first pGaN layer.

10. The member according to claim 8, wherein the passivation layer comprises aluminum oxide, aluminum nitride, silicon dioxide, or silicon nitride.

11. The member according to claim 1, wherein the member further comprises at least one intermediate GaN channel layer, at least one intermediate AlGaN barrier layer arranged over the at least one intermediate GaN channel layer and at least one intermediate pGaN layer arranged over the at least one intermediate AlGaN barrier layer respectively, wherein the at least one intermediate GaN channel layer, the at least one intermediate AlGaN barrier layer and the at least one intermediate pGaN layer are arranged between the first GaN channel layer, the first AlGaN barrier layer, the first pGaN layer and the second GaN channel layer, the second AlGaN barrier layer, and the second pGaN layer.

12. The member according to claim 1, wherein the first GaN channel layer comprises an un-intentionally doped (UID) layer.

13. The member according to claim 1, wherein at least one of the drain contact, the gate contact or the source contact is ohmic or Schottky.

14. A power device comprising a member, the member comprising:
a silicon base substrate layer;
a transition layer arranged over the silicon base substrate layer;
a gallium nitride (GaN) buffer layer arranged over the transition layer,
a first aluminum gallium nitride (AlGaN) barrier layer arranged over the GaN buffer layer, and
a first-doped gallium nitride (pGaN) layer arranged over the first AlGaN barrier layer, wherein a portion of the GaN buffer layer forms a first GaN channel layer, and wherein the first GaN channel layer, the first AlGaN barrier layer and the first pGaN layer form a first epitaxial stack, wherein the member further comprises:
a second GaN channel layer arranged over the first pGaN layer;
a second AlGaN barrier layer arranged over the second GaN channel layer;
a second pGaN layer arranged over the second AlGaN barrier layer;
a gate contact arranged over the second pGaN layer (112B);
a source contact arranged over the first AlGaN barrier layer; and
a drain contact arranged over the first AlGaN barrier layer, wherein the second pGaN layer is connected to the first pGaN layer by a connecting pGaN portion extending through a space in the second AlGaN barrier layer and the second GaN channel layer, and wherein the first pGaN layer is arranged between the source contact and the drain contact.

15. The power device according to claim 14, wherein the gate contact is arranged over the connecting pGaN portion.

16. The power device according to claim 15, wherein the connecting pGaN portion connecting the first pGaN layer and the second pGaN layer is arranged to extend above an upper surface of the second pGaN layer.

17. A method for manufacturing a member, wherein the method comprises:
arranging a gallium nitride (GaN) buffer layer arranged over a transition layer arranged over a silicon base substrate layer;
arranging a first aluminum gallium nitride (AlGaN) barrier layer over the GaN buffer layer;
arranging a first p-doped gallium nitride (pGaN) layer over the first AlGaN barrier layer;
arranging a second GaN channel layer over the first pGaN layer;
arranging a second AlGaN barrier layer over the second GaN channel layer;
arranging a second pGaN layer over the second AlGaN barrier layer;
arranging a gate contact over the second pGaN layer;
arranging a source contact over the first AlGaN barrier layer;
arranging a drain contact over the first AlGaN barrier layer;
arranging a sacrificial passivation layer over the second pGaN layer;
forming a space in the sacrificial passivation layer, the second pGaN layer, the second AlGaN barrier layer and the second GaN channel layer; and
connecting the first pGaN layer with the second pGaN layer by arranging a connecting pGaN portion extending in the space.

18. The method for manufacturing according to claim 17, wherein the method further comprises arranging the source contact and the drain contact by arranging a recess in the second AlGaN barrier layer, the second pGaN layer the second GaN channel layer, and the first pGaN layer.

19. The method for manufacturing according to claim 17, wherein the method further comprises arranging the source contact and the drain contact by arranging a recess in the second AlGaN barrier layer, the second pGaN layer the second GaN channel layer, the first pGaN layer, the first AlGaN barrier layer, and the GaN channel layer, and wherein the source contact and the drain contact are in direct contact with the GaN buffer layer.

20. The method for manufacturing according to claim 17, wherein the method further comprises manufacturing a member (that comprises:
a silicon base substrate layer;
a transition layer arranged over the silicon base substrate layer;
a GaN buffer layer arranged over the transition layer;
a first AlGaN barrier layer arranged over the GaN buffer layer;
a first pGaN layer arranged over the first AlGaN barrier layer, wherein a portion of the GaN buffer layer forms a first GaN channel layer, and wherein the first GaN channel layer, the first AlGaN barrier layer and the first pGaN layer form a first epitaxial stack;
a second GaN channel layer arranged over the first pGaN layer;
a second AlGaN barrier layer arranged over the second GaN channel layer,
a second pGaN layer arranged over the second AlGaN barrier layer,
a gate contact arranged over the second pGaN layer;
a source contact arranged over the first AlGaN barrier layer; and
a drain contact arranged over the first AlGaN barrier layer, wherein the second pGaN layer is connected to the first pGaN layer by a connecting pGaN portion extending through a space in the second AlGaN barrier layer and the second GaN channel layer, and wherein the first pGaN layer is arranged between the source contact and the drain contact.
